(19) United States
(12) Patent Application Publication
(10) Pub. No.: US 2026/0121313 A1
(43) Pub. Date: Apr. 30, 2026

(54) ELECTRONIC DEVICE, CABLE MODULE AND CASING MODULE

(71) Applicant: WISTRON CORP., New Taipei City (TW)

(72) Inventors: Chen Yang Wu, New Taipei City (TW); SHAO HUI YANG, New Taipei City (TW); KUO JUNG HSIEH, New Taipei City (TW)

(21) Appl. No.: 19/021,533

(22) Filed: Jan. 15, 2025

(30) Foreign Application Priority Data
Oct. 30, 2024 (TW) 113141432

(51) Int. Cl. H01R 12/70; H01R 12/72; H01R 12/75; H05K 7/20

(52) U.S. Cl. CPC H01R 12/7005; H01R 12/722; H01R 12/75; H05K 7/20172

(57) ABSTRACT

An electronic device includes a casing assembly, a circuit board assembly, a cable assembly and a guide mechanism. The circuit board assembly is disposed in the casing assembly and includes a circuit board and a first electrical connector, and the first electrical connector is disposed on the circuit board. The cable assembly includes a housing, a second electrical connector and a cable, the second electrical connector and the cable are disposed on the housing, and the cable is connected to the second electrical connector. The guide mechanism guides the second electrical connector to electrically connect to the first electrical connector.

### CROSS-REFERENCE TO RELATED APPLICATIONS

This non-provisional application claims priority under 35 U.S.C. § 119(a) on Patent Application No(s). 113141432 filed in Taiwan, R.O.C. on October 30, 2024, the entire contents of which are hereby incorporated by reference.

### TECHNICAL FIELD

The disclosure relates to an electronic device, a cable module and a casing module.

### BACKGROUND

In a present electronic device, an optical connector for an optical cable to electrically connect thereto is located inside the electronic device, and a depth and a height of an installation channel corresponding to the optical connector is insufficient, such that a hand of a user is difficult to hold the optical cable and put it into the installation channel for electrically connect the optical cable to the optical connector. Therefore, the user can only hold the optical cable outside the installation channel and electrically connect the optical cable to the optical connector in a blind insertion manner, which makes the optical cable difficult to electrically connect to the optical connector.

Although a clamping mechanism is currently used to assist the optical cable to electrically connect to the optical connector, the shapes and sizes of optical cables designed by various manufacturers are slightly different, which makes the clamping mechanism not applicable to various optical cables. Therefore, how to solve the aforementioned issue is one of the topics in this field.

### SUMMARY

The disclosure provides an electronic device, a cable module and a casing module which enable a cable assembly to be easily to electrically connect to an electrical connector inside the electronic device.

One embodiment of the disclosure provides an electronic device. The electronic device includes a casing assembly, a circuit board assembly, a cable assembly and a guide mechanism. The circuit board assembly is disposed in the casing assembly and includes a circuit board and a first electrical connector, and the first electrical connector is disposed on the circuit board. The cable assembly includes a housing, a second electrical connector and a cable, the second electrical connector and the cable are disposed on the housing, and the cable is connected to the second electrical connector. The guide mechanism guides the second electrical connector to electrically connect to the first electrical connector.

Another embodiment of the disclosure provides a cable module. The cable module includes a cable assembly and a guide mechanism. The cable assembly includes a housing, an electrical connector and a cable, and the electrical connector and the cable are partially disposed in the housing and are connected to each other. The guide mechanism is movably disposed on the housing and supports and guides a portion of the electrical connector located outside the housing.

Still another embodiment of the disclosure provides a casing module. The casing module is adapted to support a circuit board and guide a cable assembly to electrically connect to an electrical connector on the circuit board. The casing module includes a casing assembly and a guide mechanism. The casing assembly supports the circuit board. The guide mechanism is disposed on the casing assembly and corresponds to the electrical connector on the circuit board, and the guide mechanism guides the cable assembly to electrically connect to the electrical connector on the circuit board.

According to the electronic device, the cable module and the casing module as disclosed in the above embodiments, in a case that the installation channel corresponding to the first electrical connector is a long and narrow channel, making the cable assembly only roughly align with the first electrical connector in a blind insertion manner for electrically connecting the cable assembly to the first electrical connector, the guide mechanism is disposed on the casing assembly or is movably disposed on the housing of the cable assembly, and the guide mechanism guides the second electrical connector of the cable assembly to electrically connect to the first electrical connector of the circuit board assembly, which can help the second electrical connector of the cable assembly to electrically connect to the first electrical connector accurately.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial cross-sectional view of an electronic device according to one embodiment of the disclosure;

FIG. 2 is an exploded view of a support frame, a circuit board assembly and a cable module according to the embodiment of the disclosure;

FIG. 3 is an exploded view of the cable module according to the embodiment of the disclosure;

FIG. 4 is a side view of the cable module according to the embodiment of the disclosure;

FIGS. 5 and 6 show an electrical connection process of a second electrical connector of a cable assembly and a first electrical connector of the circuit board assembly according to the embodiment of the disclosure;

FIG. 7 is a partial perspective view of a cable module according to another embodiment of the disclosure;

FIG. 8 is a partial side view of the cable module according to the embodiment of the disclosure;

FIG. 9 is a partial cross-sectional view of an electronic device according to another embodiment of the disclosure;

FIG. 10 is an exploded view of a support frame, a guide mechanism, a circuit board assembly and a cable assembly according to the embodiment of the disclosure;

FIG. 11 is a partial enlarged perspective view of the support frame, the guide mechanism and the circuit board assembly according to the embodiment of the disclosure;

FIG. 12 is a front view of the support frame, the guide mechanism and the circuit board assembly according to the embodiment of the disclosure;

FIG. 13 is a partial enlarged cross-sectional view of the electronic device according to the embodiment of the disclosure;

FIGS. 14 and 15 show an electrical connection process of a second electrical connector of the cable assembly and a first electrical connector of the circuit board assembly according to the embodiment of the disclosure;

FIG. 16 is a partial enlarged perspective view of a support frame, a guide mechanism and a circuit board assembly according to another embodiment of the disclosure;

FIG. 17 is a front view of the support frame, the guide mechanism and the circuit board assembly according to the embodiment of the disclosure;

FIG. 18 is a cross-sectional view of the support frame, the guide mechanism and the circuit board assembly according to the embodiment of the disclosure;

FIG. 19 is a partial enlarged perspective view of a support frame, a guide mechanism and a circuit board assembly according to another embodiment of the disclosure;

FIG. 20 is a front view of the support frame, the guide mechanism and the circuit board assembly according to the embodiment of the disclosure;

FIG. 21 is a partial enlarged perspective view of a support frame, a guide mechanism and a circuit board assembly according to another embodiment of the disclosure;

FIG. 22 is a front view of the support frame, the guide mechanism and the circuit board assembly according to the embodiment of the disclosure;

FIG. 23 is a cross-sectional view of the support frame, the guide mechanism and the circuit board assembly according to the embodiment of the disclosure; and

FIG. 24 shows the guide mechanism according to the embodiment of the disclosure is turned over.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

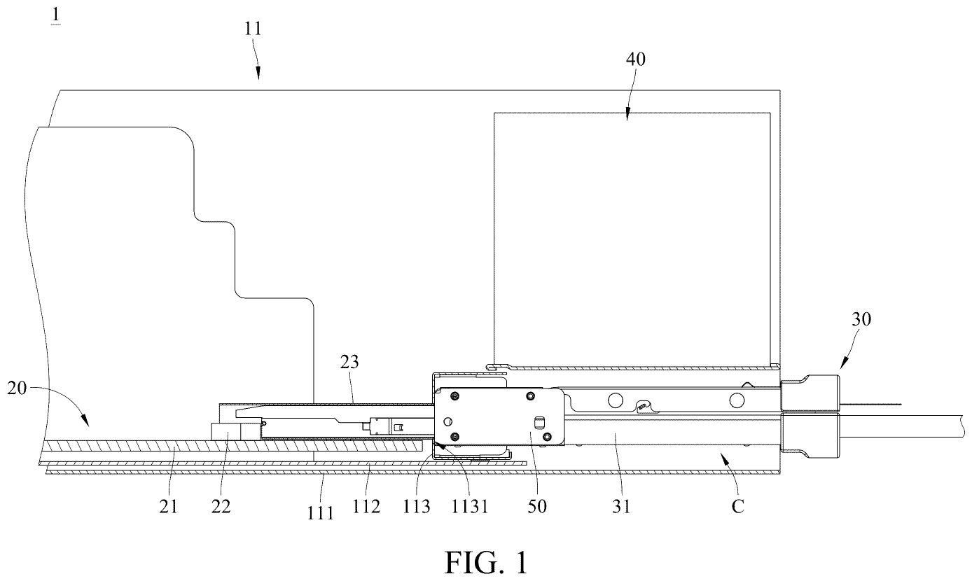

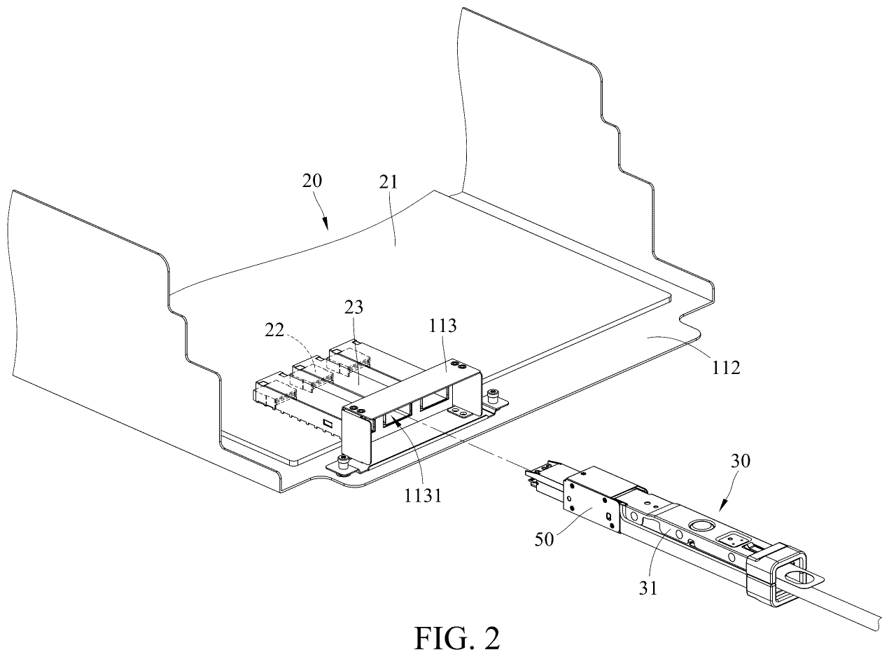

Referring to FIGS. 1 and 2, FIG. 1 is a partial cross-sectional view of an electronic device according to one embodiment of the disclosure, and FIG. 2 is an exploded view of a support frame, a circuit board assembly and a cable module according to the embodiment of the disclosure.

In this embodiment, the electronic device 1 is, for example, a server. The electronic device 1 includes a casing assembly 11, a circuit board assembly 20 and a cable module 30.

The casing assembly 11 includes a casing 111, a support frame 112 and a stopper 113. The support frame 112 is disposed in the casing 111, and the stopper 113 is disposed on the support frame 112 and is located close to an edge of the support frame 112. The stopper 113 has a through hole 1131. The circuit board assembly 20 includes a circuit board 21, a first electrical connector 22 and a cover 23. The circuit board 21 is, for example, provided with a GPU (not shown). The circuit board 21 is disposed on the support frame 112, and is located farther away from the edge of the support frame 112 than the stopper 113. The first electrical connector 22 is, for example, a female optical connector. The first electrical connector 22 is disposed on the circuit board 21. The cover 23 is fixed to the circuit board 21, and the cover 23 covers the first electrical connector 22 and extends to the through hole 1131 of the stopper 113, such that the first electrical connector 22 corresponds to the through hole 1131 of the stopper 113.

In this embodiment, the electronic device 1 may further include a fan module 40. The fan module 40 is located in the casing 111 and is located at one side of the support frame 112. A bottom of the fan module 40 is located close to a bottom of the casing 111, and the fan module 40 and the casing 111 together form a long and narrow installation channel C due to the shape of the fan module 40. The installation channel C corresponds to the first electrical connector 22 of the circuit board assembly 20, and the cable module 30 sequentially passes through the installation channel C, the stopper 113 and the cover 23 and electrically connects to the first electrical connector 22.

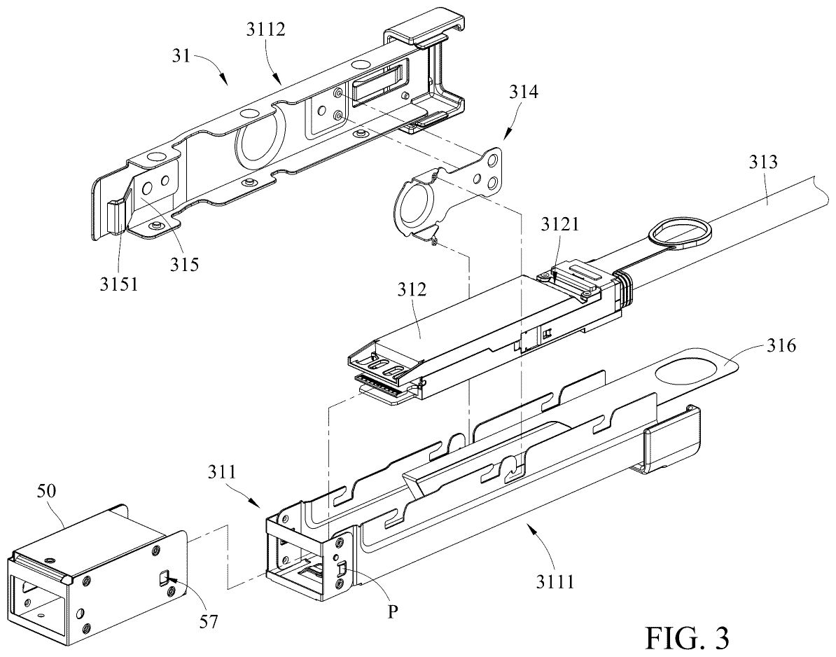

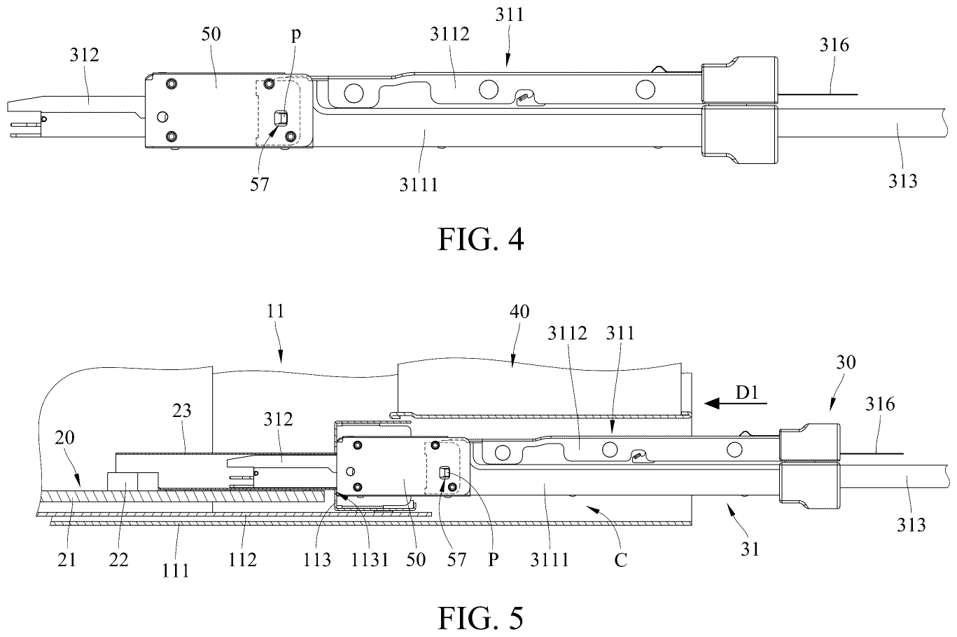

Then, referring to FIGS. 2 to 4, FIG. 3 is an exploded view of the cable module according to the embodiment of the disclosure, and FIG. 4 is a side view of the cable module according to the embodiment of the disclosure.

The cable module 30 includes a cable assembly 31 and a guide mechanism 50. The cable assembly 31 includes a housing 311, a second electrical connector 312 and a cable 313. In addition, the cable assembly 31 may further include a fastener 314, an elastic component 315 and a pull sheet 316.

The housing 311, for example, includes a base 3111 and a cover 3112. The cover 3112 is removably and slidably assembled the base 3111. For example, the base 3111 is a U-shaped structure, the cover 3112 is a U-shaped structure, two opposite walls of the base 3111 and two opposite walls of the cover 3112 are slidably assembled with each other via slide blocks and slide slots. The fastener 314 is, for example, an engagement elastic sheet. One end of the fastener 314 is fixed to the cover 3112, and another end of the fastener 314 is movable relative to the cover 3112 for fixing the cover 3112 to the base 3111 or removing the fixation relationship between the cover 3112 and the base 3111.

Note that the cover 3112 is not restricted to being slidably assembled with the base 3111. In some other embodiments, the cover may be slidably and/or rotatably assembled with the base.

Note that the cover 3112 is not restricted to being fixed to the base 3111 via the fastener 314. In some other embodiments, the cover may be fixed to the base by other means, such as screws or snap fit. In such a case, the fastener may be omitted, and the structures of the base and the cover may be correspondingly modified.

The second electrical connector 312 is, for example, a male optical connector. The second electrical connector 312 and the cable 313 are partially disposed in the housing 311 and are connected to each other. The second electrical connector 312 and the cable 313 respectively protrude from two opposite ends of the housing 311 and are partially located outside the housing 311. In other words, the housing 311 surrounds and covers a part of the second electrical connector 312 and a part of the cable 313. The second electrical connector 312 penetrates through the through hole 1131 of the stopper 113 and enters into the cover 23, such that the second electrical connector 312 of the cable assembly 31 electrically connects to the first electrical connector 22 of the circuit board assembly 20.

The second electrical connector 312 has a positioning recess 3121, the positioning recess 3121 is located in the housing 311. The elastic component 315 is fixed to the cover 3112 and is located in the housing 311. The elastic component 315 has a reverse folded portion 3151 located at one end of the elastic component 315 away from the cover 3112. The reverse folded portion 3151 corresponds to the positioning recess 3121. For example, the reverse folded portion 3151 is engaged in the positioning recess 3121.

The cooperation of the elastic component 315 and the positioning recess 3121 of the second electrical connector 312 enables the elastic component 315 to adapt the second electrical connector 312 with different thickness, and thus can firmly position the second electrical connector 312 with different thickness. Moreover, the cooperation of the reverse folded portion 3151 of the elastic component 315 and the positioning recess 3121 of the second electrical connector 312 can provide a foolproof effect during the assembly of the second electrical connector 312 and the housing 311 for preventing the second electrical connector 312 from being assembled inaccurately. In other words, in a condition that the second electrical connector 312 is reversely mounted in the housing 311, and thus the positioning recess 3121 is unable to mate the reverse folded portion 3151 of the elastic component 315, the second electrical connector 312 is unable to successfully mounted in the housing 311.

Note that the elastic component 315 and the positioning recess 3121 of the second electrical connector 312 are an optional component and an optional structure and may be omitted in some other embodiments.

The pull sheet 316 is partially located in the housing 311 and is fixed to the base 3111 of the housing 311, and the pull sheet 316 and the cable 313 extend from the inside to outside of the housing 311 along a same direction. The pull sheet 316 is configured to be pulled by a user to detach the second electrical connector 312 of the cable assembly 31 from the first electrical connector 22 of the circuit board assembly 20.

The guide mechanism 50 is, for example, a frame body. The guide mechanism 50 is slidably sleeved on the housing 311 and the second electrical connector 312, such that a length that the second electrical connector 312 protrudes from the guide mechanism 50 is adjustable. The guide mechanism 50 has a positioning hole 57, the base 3111 of the housing 311 has a positioning protrusion P, and the positioning protrusion P is engaged in the positioning hole 57 so as to position the guide mechanism 50. For example, when the positioning protrusion P of the housing 311 is engaged in the positioning hole 57 of the guide mechanism 50, the guide mechanism 50 is positioned in a guide position. At this moment, the length that the second electrical connector 312 protrudes from the guide mechanism 50 is the shortest; that is, the guide mechanism 50 is located relatively close to an electrical connection end of the second electrical connector 312.

Then, the following paragraphs will introduce the electrical connection process of the second electrical connector 312 of the cable assembly 31 and the first electrical connector 22 of the circuit board assembly 20. Referring to FIGS. 4 to 6, FIGS. 5 and 6 show an electrical connection process of a second electrical connector of a cable assembly and a first electrical connector of the circuit board assembly according to the embodiment of the disclosure.

Firstly, it should be noted that the installation channel C corresponding to the first electrical connector 22 of the circuit board assembly 20 is the long and narrow channel, and thus when one hand of the user holds the cable module 30, the hand is difficult to enter into the installation channel C along with the cable module 30. Therefore, the hand of the user can only hold the housing 311 of the cable assembly 31 of the cable module 30 outside the installation channel C, and put the cable module 30 into the installation channel C to roughly align it with first electrical connector 22 in a blind insertion manner for electrically connecting the cable module 30 to the first electrical connector 22.

In this embodiment, the housing 311 surrounds and covers a part of the cable 313, which enables the user to holder the housing 311 with higher rigidity instead of the cable 313 with lower rigidity to put the cable module 30 into the installation channel C, and thus can increase the stability of the process of putting the cable module 30 into the installation channel C.

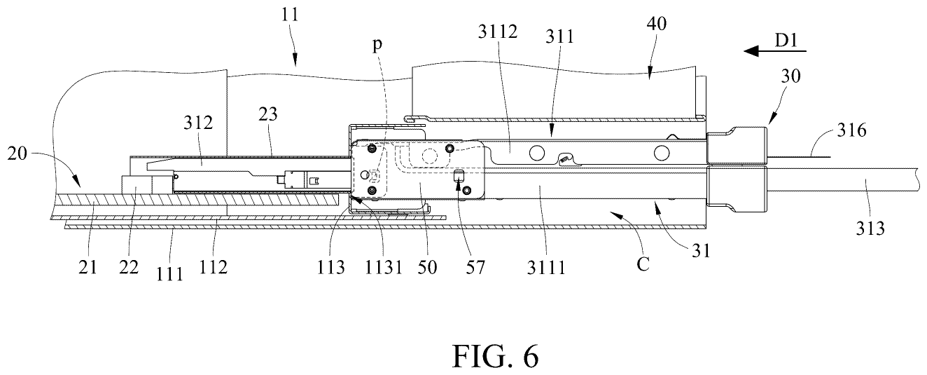

As shown in FIG. 4, before the cable module 30 is put into the installation channel C, the guide mechanism 50 is required to be in the guide position to support and guide the second electrical connector 312 and prevent the second electrical connector 312 from being inclined relative to the housing 311. Then, as shown in FIG. 5, the cable module 30 is put into the installation channel C along a direction D1, such that the second electrical connector 312 of the cable assembly 31 penetrates through the through hole 1131 of the stopper 113 and enters into the cover 23, and the guide mechanism 50 contacts the stopper 113. Then, as shown in FIG. 6, keep pushing the cable module 30 along the direction D1 forces the cable assembly 31 to slide towards the first electrical connector 22 relative to the guide mechanism 50, such that the second electrical connector 312 is electrically connected to the first electrical connector 22. As a result, the electrical connection process of the second electrical connector 312 of the cable assembly 31 and the first electrical connector 22 of the circuit board assembly 20 is finished.

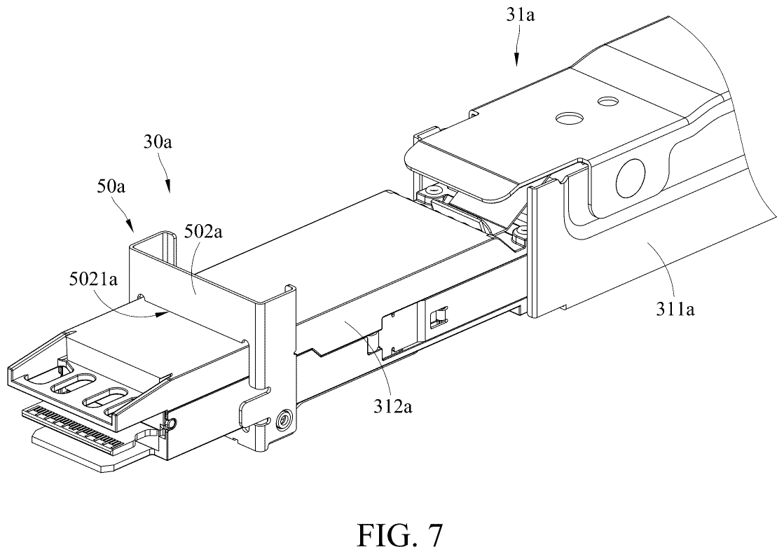

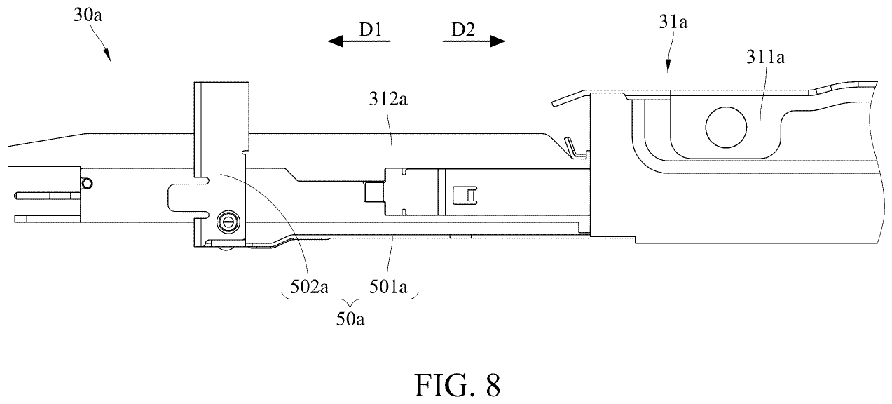

Referring to FIGS. 7 and 8, FIG. 7 is a partial perspective view of a cable module according to another embodiment of the disclosure, and FIG. 8 is a partial side view of the cable module according to the embodiment of the disclosure.

The cable module 30a of this embodiment is similar to the cable module 30 of the previous embodiment, the main difference between them is the structure of the guide mechanism, and thus the following paragraph mainly introduces a guide mechanism 50a of the cable module 30a of this embodiment while the same parts between the cable module 30a of this embodiment and the cable module 30 of the previous embodiment will not be repeatedly introduced hereinafter.

In this embodiment, the guide mechanism 50a of the cable module 30a includes a mount portion 501a and a frame portion 502a connected to each other. The mount portion 501a of the guide mechanism 50a is slidably disposed on a housing 311a of a cable assembly 31a of the cable module 30a. The frame portion 502a of the guide mechanism 50a has a guide through hole 5021a, and a second electrical connector 312a of the cable assembly 31a of the cable module 30a is disposed through the guide through hole 5021a. The mount portion 501a of the guide mechanism 50a is slidable relative to the housing 311a, such that the frame portion 502a can be moved to be relatively close to the housing 311a along a direction D2 or far away from the housing 311a along a direction D1. The guide mechanism 50a enables the second electrical connector 312a to electrically connect to a first electrical connector of a circuit board assembly accurately and successfully.

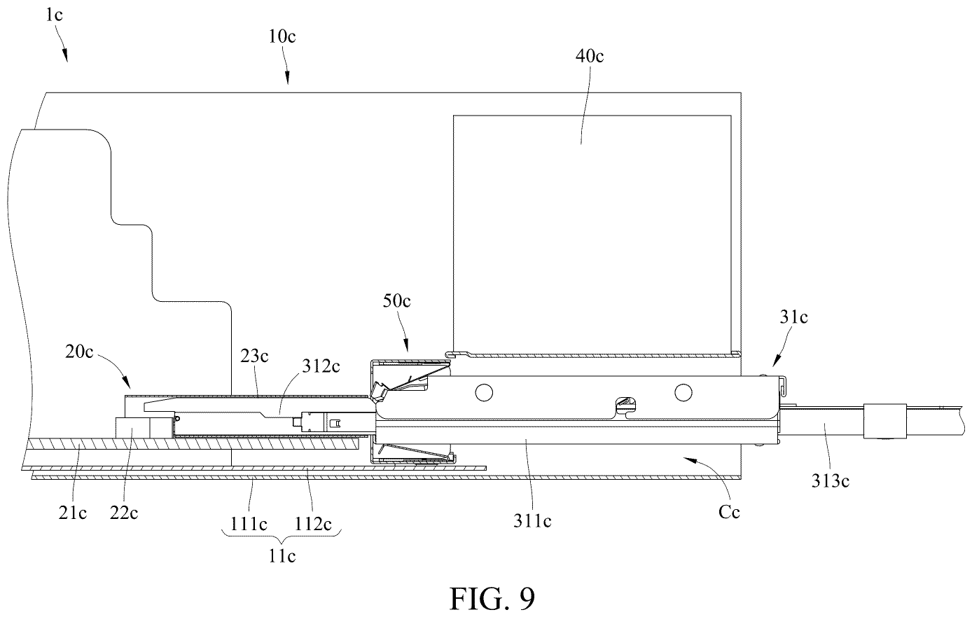

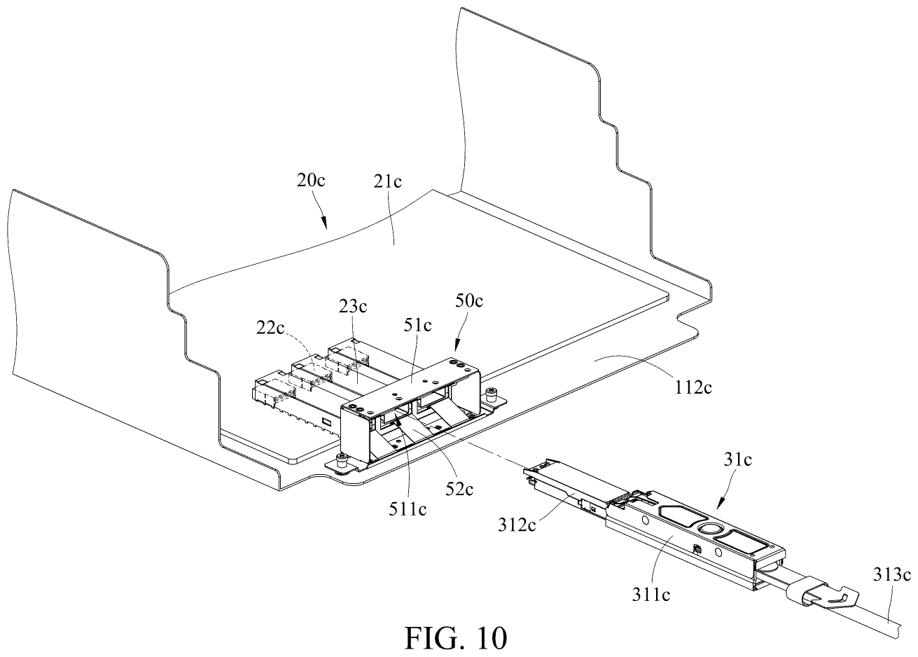

Referring to FIGS. 9 and 10, FIG. 9 is a partial cross-sectional view of an electronic device according to another embodiment of the disclosure, and FIG. 10 is an exploded view of a support frame, a guide mechanism, a circuit board assembly and a cable assembly according to the embodiment of the disclosure.

In this embodiment, the electronic device 1c is, for example, a server. The electronic device 1c includes a casing module 10c, a circuit board assembly 20c and a cable assembly 31c. The casing module 10c includes a casing assembly 11c and a guide mechanism 50c. The casing assembly 11c includes a casing 111c and a support frame 112c. The support frame 112c is disposed in the casing 111c, and the guide mechanism 50c is disposed on the support frame 112c.

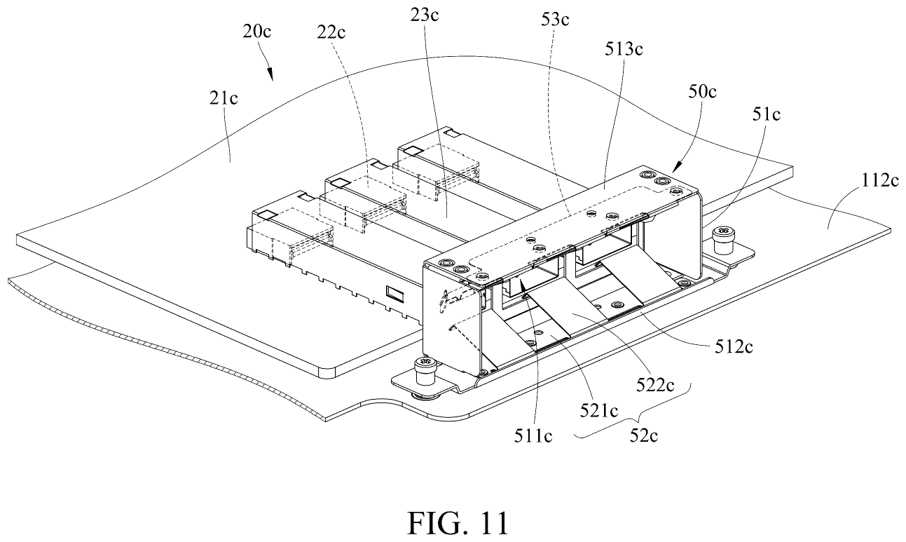

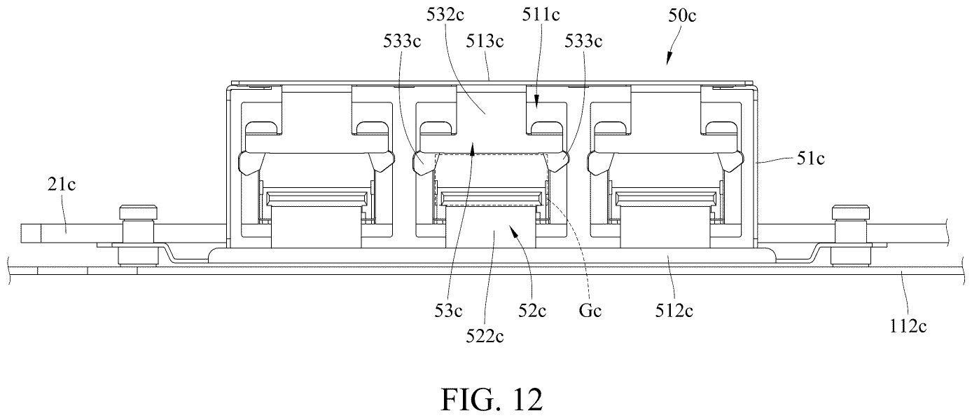

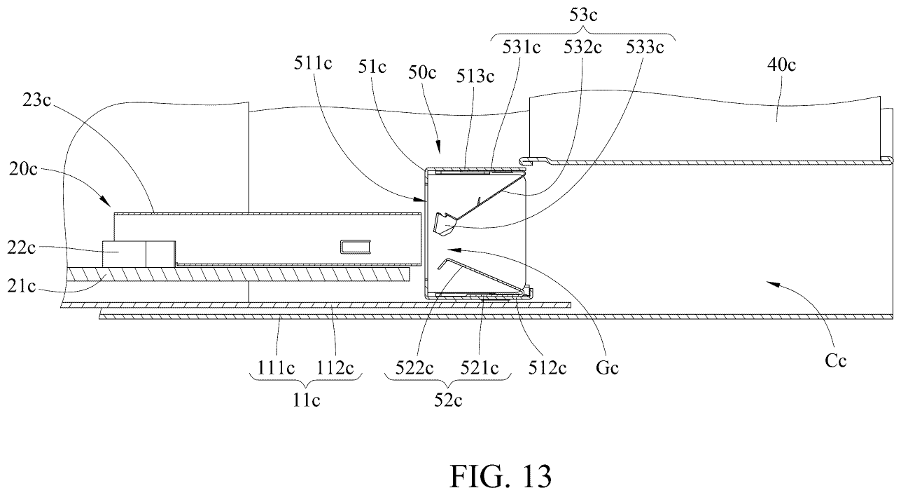

Then, referring to FIGS. 11 to 13, FIG. 11 is a partial enlarged perspective view of the support frame, the guide mechanism and the circuit board assembly according to the embodiment of the disclosure, FIG. 12 is a front view of the support frame, the guide mechanism and the circuit board assembly according to the embodiment of the disclosure, and FIG. 13 is a partial enlarged cross-sectional view of the electronic device according to the embodiment of the disclosure.

The guide mechanism 50c includes a frame body 51c, a first guide component 52c and a second guide component 53c. The frame body 51c is fixed on the support frame 112c, for example, via screws and is located close to an edge of the support frame 112c. The frame body 51c has a through hole 511c. The first guide component 52c includes a first fixed portion 521c and a first movable portion 522c connected to each other. The first fixed portion 521c is fixed to a bottom portion 512c of the frame body 51c, and the first movable portion 522c extend towards a top portion 513c of the frame body 51c and is movable relative to the first fixed portion 521c. The second guide component 53c includes a second fixed portion 531c, a second movable portion 532c and two bent portions 533c. The second fixed portion 531c is fixed to the top portion 513c of the frame body 51c, the second movable portion 532c is movably connected to the second fixed portion 531c and extends towards the bottom portion 512c of the frame body 51c, and the two bent portions 533c are respectively connected to two opposite sides of the second movable portion 532c. The first movable portion 522c, the second movable portion 532c and the bent portions 533c together form a guide hole Gc. The guide hole Gc is located closer to the edge of the support frame 112c than the through hole 511c, and a size of the guide hole Gc is smaller than a size of the through hole 511c.

The circuit board assembly 20c includes a circuit board 21c, a first electrical connector 22c and a cover 23c. The circuit board 21c is, for example, provided with a GPU (not shown). The circuit board 21c is disposed on the support frame 112c, and is located farther away from the edge of the support frame 112c than the frame body 51c of the guide mechanism 50c. The first electrical connector 22c is, for example, a female optical connector. The first electrical connector 22c is disposed on the circuit board 21c. The cover 23c is fixed to the circuit board 21c, and the cover 23c covers the first electrical connector 22c and extends to the through hole 511c of the frame body 51c of the guide mechanism 50c, such that the first electrical connector 22c corresponds to the guide hole Gc and the through hole 511c of the frame body 51c of the guide mechanism 50c.

As shown in FIGS. 9 and 10, the cable assembly 31c includes a housing 311c, a second electrical connector 312c and a cable 313c. The second electrical connector 312c is, for example, a male optical connector. The second electrical connector 312c and the cable 313c are partially disposed in the housing 311c and are connected to each other. The second electrical connector 312c and the cable 313c respectively protrude from two opposite ends of the housing 311c and are partially located outside the housing 311c. In other words, the housing 311c surrounds and covers a part of the second electrical connector 312c and a part of the cable 313c.

As shown in FIG. 9, the electronic device 1c may further include a fan module 40c. The fan module 40c is located in the casing 111c and is located at one side of the support frame 112c. A bottom of the fan module 40c is located close to a bottom of the casing 111c, and the fan module 40c and the casing 11c1 together form a long and narrow installation channel Cc due to the shape of the fan module 40c. The installation channel Cc corresponds to the first electrical connector 22c of the circuit board assembly 20c, and the cable assembly 31c sequentially passes through the installation channel Cc, the guide mechanism 50c and the cover 23c and electrically connects to the first electrical connector 22c.

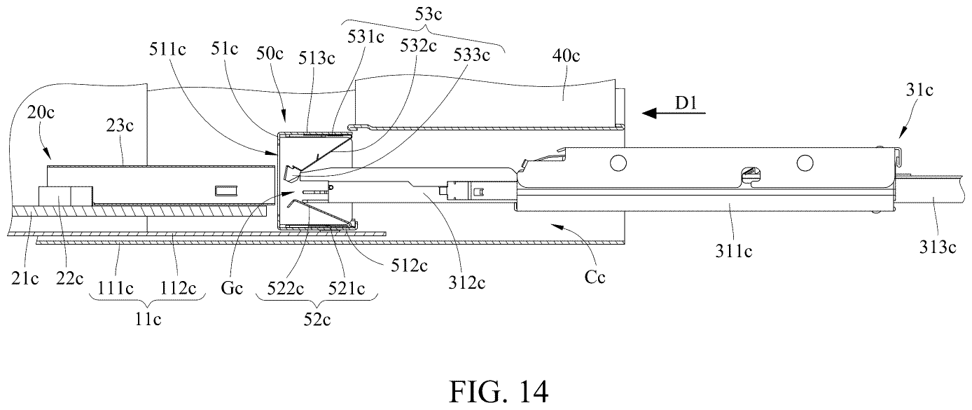

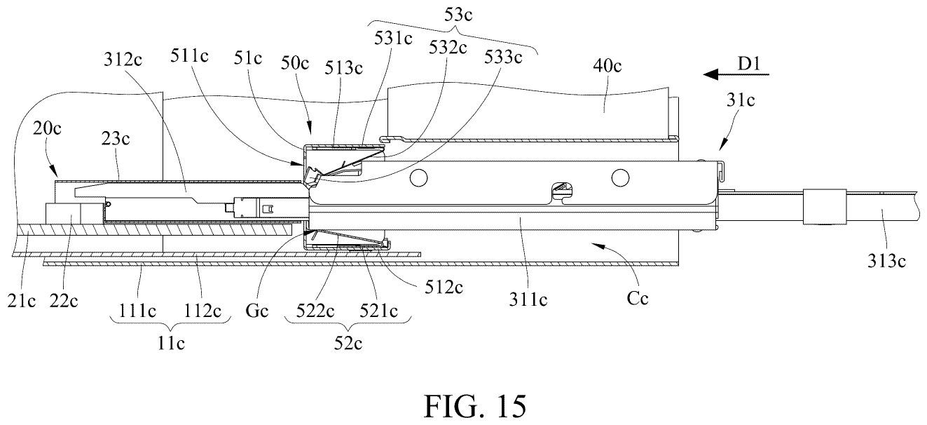

Then, the following paragraphs will introduce the electrical connection process of the second electrical connector 312c of the cable assembly 31c and the first electrical connector 22c of the circuit board assembly 20c. FIGS. 14 and 15 show an electrical connection process of a second electrical connector of the cable assembly and a first electrical connector of the circuit board assembly according to the embodiment of the disclosure

Firstly, it should be noted that the installation channel Cc corresponding to the first electrical connector 22c of the circuit board assembly 20c is the long and narrow channel, and thus when one hand of the user holds the cable assembly 31c, the hand is difficult to enter into the installation channel Cc along with the cable assembly 31c. Therefore, the hand of the user can only hold the housing 311c of the cable assembly 31c outside the installation channel Cc, and put the cable assembly 31c into the installation channel Cc to roughly align it with first electrical connector 22c in a blind insertion manner for electrically connecting the cable assembly 31c to the first electrical connector 22c.

In this embodiment, the housing 311c surrounds and covers a part of the cable 313c, which enables the user to holder the housing 311c with higher rigidity instead of the cable 313c with lower rigidity to put the cable assembly 31c into the installation channel Cc, and thus can increase the stability of the process of putting the cable assembly 31c into the installation channel Cc.

As shown in FIG. 14, after the cable assembly 31c is placed into the installation channel Cc along the direction D1, the second electrical connector 312c of the cable assembly 31c can contact the first movable portion 522c of the first guide component 52c and the second movable portion 532c and the bent portions 533c of the second guide component 53c of the guide mechanism 50c. Then, as shown in FIG. 15, keep pushing the cable assembly 31c along the direction D1 forces the cable assembly 31c to be guided by the first guide component 52c and the second guide component 53c so as to sequentially pass through the guide hole Gc and the through hole 511c of the frame body 51c, such that the cable assembly 31c enters into the cover 23c and electrically connects to the first electrical connector 22c of the circuit board assembly 20c. As a result, the electrical connection process of the second electrical connector 312c of the cable assembly 31c and the first electrical connector 22c of the circuit board assembly 20c is finished.

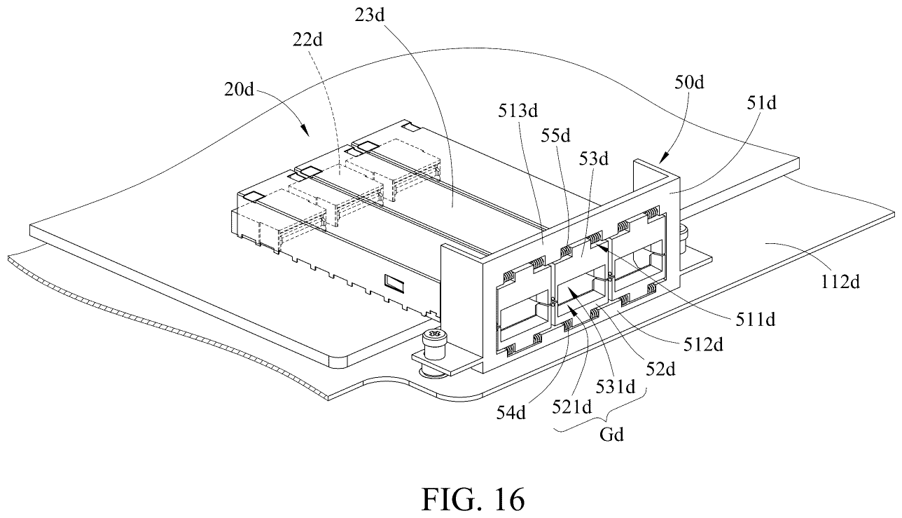

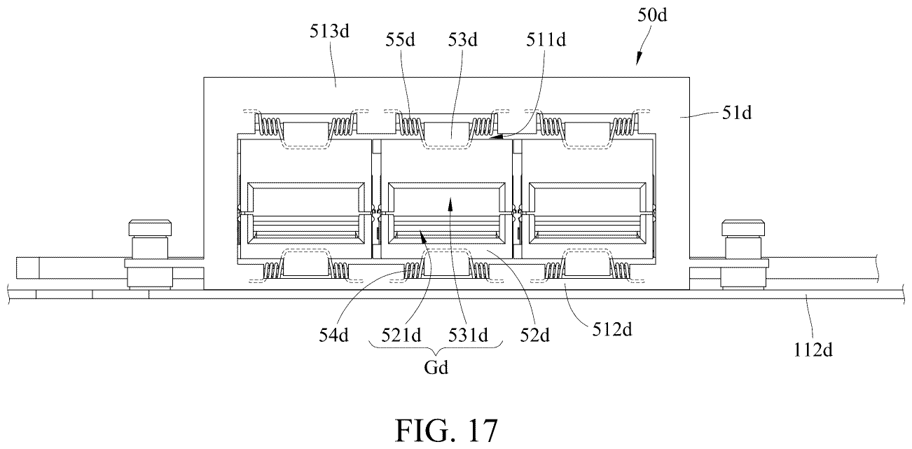

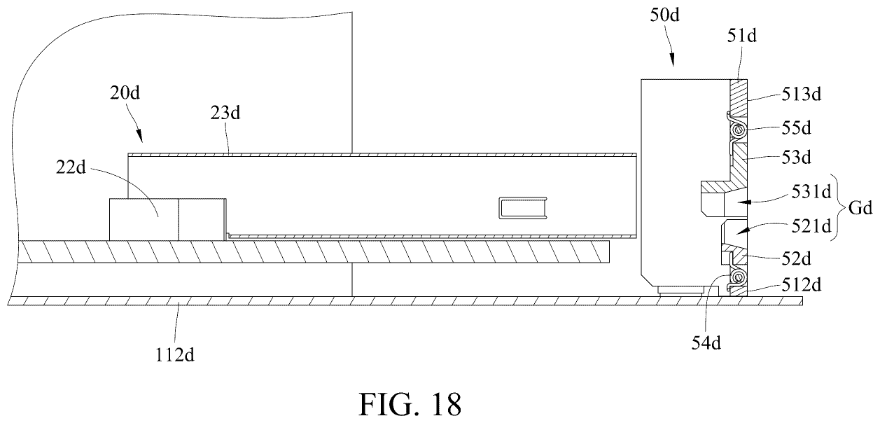

Referring to FIGS. 16 to 18, FIG. 16 is a partial enlarged perspective view of a support frame, a guide mechanism and a circuit board assembly according to another embodiment of the disclosure, FIG. 17 is a front view of the support frame, the guide mechanism and the circuit board assembly according to the embodiment of the disclosure, and FIG. 18 is a cross-sectional view of the support frame, the guide mechanism and the circuit board assembly according to the embodiment of the disclosure.

A support frame 112d, a guide mechanism 50d and a circuit board assembly 20d of this embodiment is similar to the support frame 112c, the guide mechanism 50c and the circuit board assembly 20c of the previous embodiment, the main difference between them is the structure of the guide mechanism, and thus the following paragraphs will mainly introduce the guide mechanism 50d of this embodiment while other parts of this embodiment can be referred to the aforementioned paragraphs and will not be repeatedly introduced hereinafter.

In this embodiment, a first guide component 52d and a second guide component 53d of the guide mechanism 50d are respectively pivotably disposed on a bottom portion 512d and a top portion 513d of a frame body 51d, and the first guide component 52d and the second guide component 53d are located in a through hole 511d of the frame body 51d. The first guide component 52d has a first recess 521d, and the second guide component 53d has a second recess 531d. The first recess 521d and the second recess 531d together form a guide hole Gd. In addition, the guide mechanism 50d further includes a first elastic component 54d and a second elastic component 55d. The first elastic component 54d and the second elastic component 55d are, for example, torsion springs. Two opposite ends of the first elastic component 54d are respectively in contact with the first guide component 52d and the frame body 51d, and two opposite ends of the second elastic component 55d are respectively in contact with the second guide component 53d and the frame body 51d. The first elastic component 54d and the second elastic component 55d respectively provide forces to the first guide component 52d and the second guide component 53d for recovering the first guide component 52d and the second guide component 53d back to their original positions after be pivoted by external forces.

In this embodiment, the first guide component 52d and the second guide component 53d are configured to guide the second electrical connector 312c of the cable assembly 31c shown in FIG. 10 to pass through the guide hole Gd, such that the second electrical connector 312c enters into a cover 23d of the circuit board assembly 20d and electrically connects to a first electrical connector 22d of the circuit board assembly 20d.

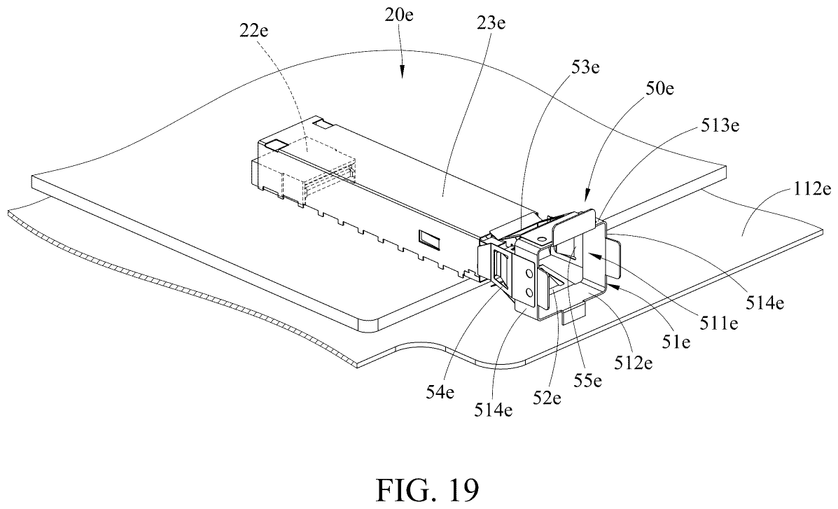

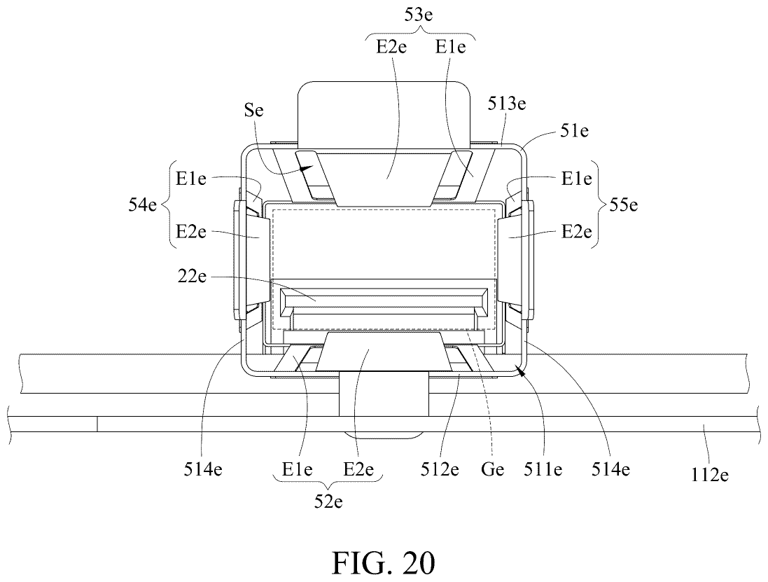

Then, referring to FIGS. 19 and 20, FIG. 19 is a partial enlarged perspective view of a support frame, a guide mechanism and a circuit board assembly according to another embodiment of the disclosure, and FIG. 20 is a front view of the support frame, the guide mechanism and the circuit board assembly according to the embodiment of the disclosure.

A support frame 112e, a guide mechanism 50e and a circuit board assembly 20e of this embodiment is similar to the support frame 112c, the guide mechanism 50c and the circuit board assembly 20c of the previous embodiment, the main difference between them is the structure of the guide mechanism, and thus the following paragraphs will mainly introduce the guide mechanism 50e of this embodiment while other parts of this embodiment can be referred to the aforementioned paragraphs and will not be repeatedly introduced hereinafter.

In this embodiment, the guide mechanism 50e includes not only a first guide component 52e and a second guide component 53e, but also a third guide component 54e and a fourth guide component 55e. The first guide component 52e, the second guide component 53e, the third guide component 54e and the fourth guide component 55e are elastic sheets. The first guide component 52e and the second guide component 53e are respectively fixed to a bottom portion 512e and a top portion 513e of a frame body 51e of the guide mechanism 50e, and the third guide component 54e and the fourth guide component 55e are respectively fixed to two side portions 514e of the frame body 51e of the guide mechanism 50e.

Each of the first guide component 52e, the second guide component 53e, the third guide component 54e and the fourth guide component 55e, for example, includes an annular portion E1e and a sheet portion E2e. Taking one of the guide components for example, the annular portion E1e is fixed to the frame body 51e and surrounds a slot Se. One end of the sheet portion E2e is connected to the annular portion E1e, and another end of the sheet portion E2e is movable relative to the annular portion E1e in the slot Se. The sheet portions E2e of the first guide component 52e, the second guide component 53e, the third guide component 54e and the fourth guide component 55e together form a guide hole Ge, and the guide hole Ge is located farther away from an edge of the support frame 112e than a through hole 511e of the frame body 51e.

In this embodiment, the first guide component 52e, the second guide component 53e, the third guide component 54e and the fourth guide component 55e are configured to guide the second electrical connector 312c of the cable assembly 31c shown FIG. 10 to pass through the guide hole Ge, such that the second electrical connector 312c enters into a cover 23e and electrically connected to a first electrical connector 22e of the circuit board assembly 20e.

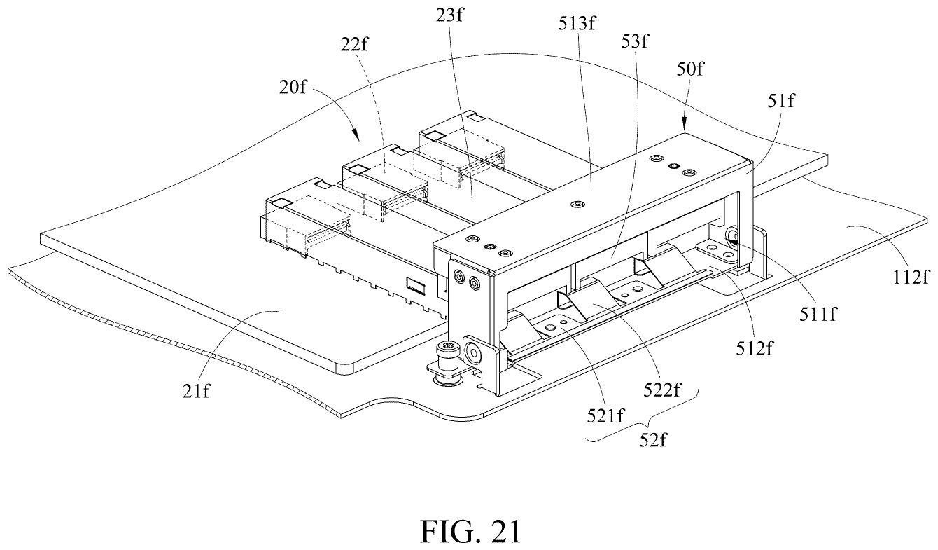

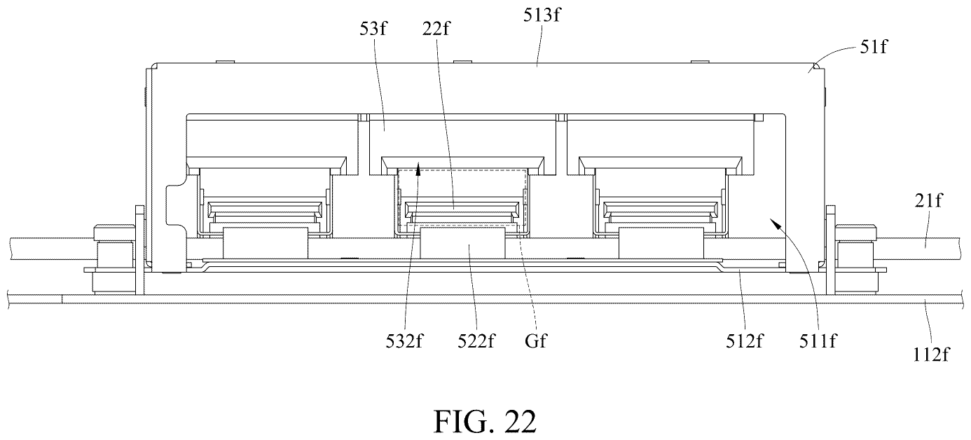

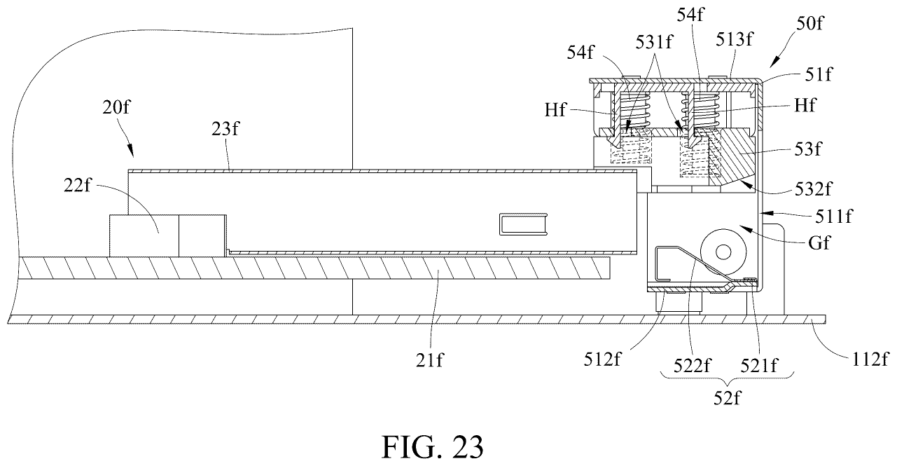

Referring to FIGS. 21 to 23, FIG. 21 is a partial enlarged perspective view of a support frame, a guide mechanism and a circuit board assembly according to another embodiment of the disclosure, FIG. 22 is a front view of the support frame, the guide mechanism and the circuit board assembly according to the embodiment of the disclosure, and FIG. 23 is a cross-sectional view of the support frame, the guide mechanism and the circuit board assembly according to the embodiment of the disclosure.

A support frame 112f, a guide mechanism 50f and a circuit board assembly 20f of this embodiment is similar to the support frame 112c, the guide mechanism 50c and the circuit board assembly 20c of the previous embodiment, the main difference between them is the structure of the guide mechanism, and thus the following paragraphs will mainly introduce the guide mechanism 50f of this embodiment while other parts of this embodiment can be referred to the aforementioned paragraphs and will not be repeatedly introduced hereinafter.

In this embodiment, a first guide component 52f of the guide mechanism 50f is an elastic sheet, and a second guide component 53f of the guide mechanism 50f is a slidable block. More specifically, the first guide component 52f includes a fixed portion 521f and a movable portion 522f connected to each other. The fixed portion 521f is fixed to a bottom portion 512f of a frame body 51f, and the movable portion 522f extends towards a top portion 513f of the frame body 51f and is movable relative to the fixed portion 521f. In addition, the top portion 513f of the frame body 51f is provided with a plurality of hook structures Hf extending towards the bottom portion 512f, and the second guide component 53f has a plurality of mount holes 531f. The hook structures Hf of the top portion 513f of the frame body 51f are respectively mounted in the mount holes 531f of the second guide component 53f, such that the second guide component 53f is slidably disposed on the top portion 513f of the frame body 51f via the hook structures Hf. The hook structures Hf can prevent the second guide component 53f from being detached from the top portion 513f of the frame body 51f. The second guide component 53f further has an inclined guide surface 532f, and the movable portion 522f of the first guide component 52f and the inclined guide surface 532f of the second guide component 53f together form a guide hole Gf. The guide hole Gf is located farther away from an edge of the support frame 112f than a through hole 511f of the frame body 51f.

In this embodiment, the movable portion 522f of the first guide component 52f and the inclined guide surface 532f of the second guide component 53f are configured to guide the second electrical connector 312c of the cable assembly 31c shown in FIG. 10 to pass through the guide hole Gf, such that the second electrical connector 312c enters into a cover 23f and electrically connects to the first electrical connector 22f of the circuit board assembly 20f.

In this embodiment, the guide mechanism 50f further includes a plurality of elastic components 54f, and the elastic components 54f are compression springs. Two opposite ends of the elastic components 54f are respectively in contact with the top portion 513f of the frame body 51f and the second guide component 53f. The elastic components 54f provides forces to the second guide component 53f to move the second guide component 53f towards the bottom portion 512f of the frame body 51f.

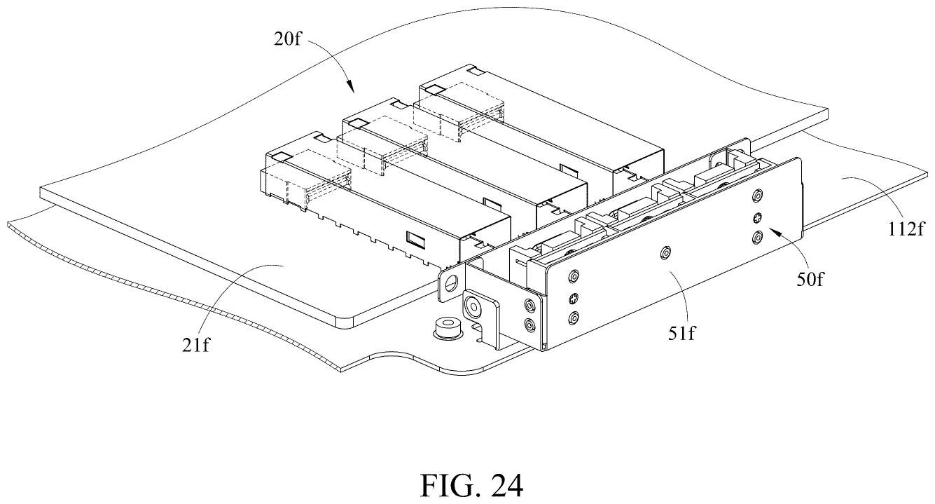

Referring to FIG. 24, FIG. 24 shows the guide mechanism according to the embodiment of the disclosure is turned over.

In this embodiment, the frame body 51f is pivotably disposed on the support frame 112f. When screws used to fix the frame body 51f on the support frame 112f are removed, the frame body 51f can be turned over to yield more space for preventing the guide mechanism 50f from affecting installations of electronic components (e.g., GPU) on the circuit board 21f.

According to the electronic devices, the cable modules and the casing modules as disclosed in the above embodiments, in a case that the installation channel corresponding to the first electrical connector is a long and narrow channel, making the cable assembly only roughly align with the first electrical connector in a blind insertion manner for electrically connecting the cable assembly to the first electrical connector, the guide mechanism is disposed on the casing assembly or is movably disposed on the housing of the cable assembly, and the guide mechanism guides the second electrical connector of the cable assembly to electrically connect to the first electrical connector of the circuit board assembly, which can help the second electrical connector of the cable assembly to electrically connect to the first electrical connector accurately. As a result, no matter which kind of the cable assembly is, the assistance of the guide mechanism enables the second electrical connector of the cable assembly to successfully electrically connect to the first electrical connector of the circuit board assembly.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. An electronic device, comprising:
a casing assembly;
a circuit board assembly, disposed in the casing assembly and comprising a circuit board and a first electrical connector, wherein the first electrical connector is disposed on the circuit board;
a cable assembly, comprising a housing, a second electrical connector and a cable, wherein the second electrical connector and the cable are disposed on the housing, and the cable is connected to the second electrical connector; and
a guide mechanism, guiding the second electrical connector to electrically connect to the first electrical connector.

2. The electronic device according to claim 1, where the guide mechanism is movably disposed on the housing of the cable assembly.

3. The electronic device according to claim 2, wherein the guide mechanism is slidably sleeved on the housing and supports the second electrical connector.

4. The electronic device according to claim 2, wherein the guide mechanism comprises a mount portion and a frame portion connected to each other, the mount portion is slidably disposed on the housing, the frame portion comprises a guide through hole, and the second electrical connector is disposed through the guide through hole.

5. The electronic device according to claim 1, wherein the cable assembly further comprises an elastic component, the second electrical connector has a positioning recess, and the elastic component is disposed in the housing and corresponds to the positioning recess.

6. The electronic device according to claim 1, wherein the cable assembly further comprises a fastener, the housing comprises a base and a cover, the fastener is disposed between the base and the cover, and the cover is removably connected to the base via the fastener.

7. The electronic device according to claim 1, further comprising a fan module, wherein the fan module is disposed in the casing assembly and is spaced apart from a bottom of the casing assembly so as to form an installation channel, the installation channel corresponds to the first electrical connector of the circuit board assembly, and the guide mechanism guides the second electrical connector to pass through the installation channel and electrically connect to the first electrical connector.

8. The electronic device according to claim 1, wherein the guide mechanism is disposed on the casing assembly.

9. The electronic device according to claim 8, wherein the guide mechanism comprises a frame body, a first guide component and a second guide component, the frame body is disposed on the casing assembly and has a through hole corresponding to the first electrical connector, the first guide component and the second guide component are respectively disposed on a bottom portion and a top portion of the frame body, the first guide component and the second guide component together form a guide hole, a size of the guide hole is smaller than a size of the through hole, the guide hole corresponds to the first electrical connector, the guide hole allows the second electrical connector of the cable assembly to pass therethrough and electrically connect to the first electrical connector.

10. The electronic device according to claim 9, wherein the first guide component and the second guide component are elastic sheets.

11. The electronic device according to claim 10, wherein the first guide component comprises a first fixed portion and a first movable portion connected to each other, the first fixed portion is fixed to the bottom portion of the frame body, the first movable portion extends towards the top portion of the frame body and is movable relative to the first fixed portion, the second guide component comprises a second fixed portion, a second movable portion and two bent portions, the second fixed portion is fixed to the top portion of the frame body, the second movable portion is movably connected to the second fixed portion and extends towards the bottom portion of the frame body, the two bent portions are respectively connected to two opposite sides of the second movable portion, and the first movable portion, the second movable portion and the two bent portions together form the guide hole.

12. The electronic device according to claim 9, wherein the guide mechanism further comprises a third guide component and a fourth guide component respectively disposed on two side portions of the frame body, and the first guide component, the second guide component, the third guide component and the fourth guide component together form the guide hole.

13. The electronic device according to claim 9, wherein the first guide component and the second guide component are respectively pivotably disposed on the bottom portion and the top portion of the frame body, the first guide component has a first recess, the second guide component has a second recess, and the first recess and the second recess together form the guide hole.

14. The electronic device according to claim 13, wherein the guide mechanism further comprises a first elastic component and a second elastic component respectively disposed on the first guide component and the second guide component, and the first elastic component and the second elastic component provide forces to the first guide component and the second guide component to recover the first guide component and the second guide component to original positions.

15. The electronic device according to claim 9, wherein the first guide component is an elastic sheet, and the second guide component is slidable block.

16. The electronic device according to claim 15, wherein the first guide component comprises a fixed portion and a movable portion connected to each other, the fixed portion is fixed to the bottom portion of the frame body, the movable portion extends towards the top portion of the frame body and is movable relative to the fixed portion, the second guide component has an inclined guide surface, and the movable portion and the inclined guide surface together form the guide hole.

17. The electronic device according to claim 16, wherein the guide mechanism further comprises an elastic component, the elastic component is disposed on the second guide component, and provides a force to the second guide component to move the second guide component towards the bottom portion of the frame body.

18. The electronic device according to claim 9, wherein the frame body is pivotably disposed on the casing assembly.

19. A cable module, comprising:
a cable assembly, comprising a housing, an electrical connector and a cable, wherein the electrical connector and the cable are partially disposed in the housing and are connected to each other; and
a guide mechanism, movably disposed on the housing and supporting and guiding a portion of the electrical connector located outside the housing.

20. A casing module, adapted to support a circuit board and guide a cable assembly to electrically connect to an electrical connector on the circuit board, the casing module comprising:
a casing assembly, supporting the circuit board; and
a guide mechanism, disposed on the casing assembly and corresponding to the electrical connector on the circuit board, wherein the guide mechanism guides the cable assembly to electrically connect to the electrical connector on the circuit board.
